(19) United States
(12) Patent Application Publication
(10) Pub. No.: US 2026/0269123 A1
(43) Pub. Date: Sep. 10, 2026

(54) MOUNTING STRUCTURE FOR ELECTRONIC COMPONENT

(71) Applicant: Murata Manufacturing Co., Ltd., Nagaokakyo-shi (JP)

(72) Inventors: Takahito SHIMIZU, Nagaokakyo-shi (JP); Masato KIMURA, Nagaokakyo-shi (JP); Yuta KUROSU, Nagaokakyo-shi (JP)

(73) Assignee: Murata Manufacturing Co., Ltd., Nagaokakyo-shi (JP)

(21) Appl. No.: 19/661,679

(22) Filed: Apr. 29, 2026

Related U.S. Application Data
(63) Continuation of application No. PCT/JP2024/025904, filed on Jul. 19, 2024.

(30) Foreign Application Priority Data
Nov. 7, 2023 (JP) 2023-190269

(51) Int. Cl. H01G 2/06; H01G 4/30

(52) U.S. Cl. CPC H01G 2/065; H01G 4/30

(57) ABSTRACT

A mounting structure includes: a pair of lands disposed on a substrate so as to be apart from each other; a solder disposed on each of the lands; and an electronic component that has a component body and a pair of external electrodes, each of the external electrodes being connected to the land via the solder. Each of the external electrodes includes an extension part that covers a main surface and a side surface of the component body. When a direction orthogonal to the surface of the substrate is defined as the Z-direction, the dimension in the Z-direction of a gap defined between the land and the extension part is 1-100 μm, inclusive.

### CROSS-REFERENCE TO RELATED APPLICATIONS

This application is a Continuation Application of PCT Application No. PCT/JP2024/025904, filed on Jul. 19, 2024, which claims the benefit of priority to Japanese Patent Application No. 2023-190269, filed on Nov. 7, 2023. The entire contents of each application are hereby incorporated herein by reference.

### BACKGROUND

### 1. Field

The present disclosure relates to a mounting structure for electronic components.

### 2. Description of the Related Art

Conventionally, two-terminal electronic components such as multilayer ceramic capacitors and inductors are mounted on substrates having circuits by soldering. Patent Document 1 discloses a mounting structure in which a pair of external electrodes provided at both ends in the length direction of a multilayer ceramic capacitor is connected to a pair of electrode pads provided on a substrate by soldering.

Patent Document 1: Japanese Unexamined Patent publication, Publication No. 2014-086606

### SUMMARY

Aspects are directed to a mounting structure for an electronic component is provided which includes: a pair of lands provided on a substrate and spaced apart from each other; solder provided on each of the pair of lands; and an electronic component including a component main body including dielectric layers and internal electrode layers that are laminated, a pair of main surfaces opposed to each other in a lamination direction, a pair of lateral surfaces opposed to each other in a width direction orthogonal to the lamination direction, and a pair of end surfaces opposed to each other in a length direction orthogonal to the lamination direction and the width direction, and a pair of external electrodes each provided on a corresponding one of the pair of end surfaces, each of the pair of external electrodes being connected to a corresponding one of the pair of lands via the solder. Each of the pair of external electrodes includes an extension portion extending to at least a portion of each of the main surfaces and each of the lateral surfaces. When a direction substantially orthogonal to a surface of the substrate is defined as a Z direction, a dimension in the Z direction of the solder provided in a region between a corresponding one of the pair of lands and the extension portion is 1 μm or more and 100 μm or less.

### BRIEF DESCRIPTION OF THE DRAWINGS

FIG. 1 is a perspective view showing a multilayer ceramic capacitor as an electronic component applied to a mounting structure for electronic components according to the first embodiment.

FIG. 2 is a plan view showing the mounting structure for electronic components according to the first embodiment.

FIG. 3 is a cross-sectional view taken along the line III-III in FIG. 2.

FIG. 4 is a partially enlarged cross-sectional view showing a main portion of the mounting structure for electronic components according to the first embodiment.

FIG. 5 is a plan view showing the mounting structure for electronic components according to the second embodiment.

FIG. 6 is a cross-sectional view taken along the line VI-VI in FIG. 5.

### DETAILED DESCRIPTION OF THE EXAMPLE EMBODIMENTS

When the environmental temperature changes during the use of electronic equipment, stress is generated in electronic components due to differences in linear expansion coefficients of the electronic components, solder, and substrate. When stress is generated in electronic components, cracks may occur at the boundaries between the base body and the external electrodes. Furthermore, when electronic components with such cracks are exposed to a humid environment, internal insulation resistance decreases and heat is generated, which may cause damage to the electronic equipment.

Therefore, the disclosure is directed to providing a mounting structure for each electronic component that is able to suppress the occurrence of cracks in the electronic components.

Hereinafter, embodiments will be described with reference to the drawings.

### First Embodiment

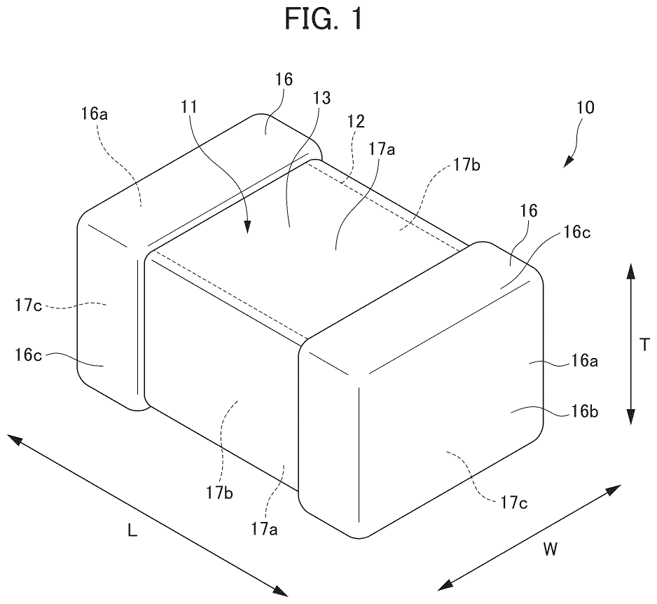

FIG. 1 shows a multilayer ceramic capacitor 10 as an electronic component applied to a mounting structure for electronic components according to the first embodiment. The first embodiment is one configuration of a structure for mounting the multilayer ceramic capacitor 10 on a substrate.

The multilayer ceramic capacitor 10 has a substantially rectangular parallelepiped shape as a whole. The multilayer ceramic capacitor 10 includes a component main body 11 and a pair of external electrodes 16. The component main body 11 includes an inner layer portion 12 including a plurality of dielectric layers 121 and internal electrode layers 122 that are alternately laminated.

In the present specification, the direction in which the dielectric layers 121 and the internal electrode layers 122 are laminated is defined as “lamination direction T”. The direction orthogonal to the lamination direction T is defined as “length direction L”. The direction orthogonal to the lamination direction T and the length direction L is defined as “width direction W”. The pair of external electrodes 16 are aligned in the length direction L.

Examples of the dimensions of the multilayer ceramic capacitor 10 include the length direction L of 0.2 mm or more and 1.7 mm or less, the width direction W of 0.12 mm or more and 0.9 mm or less, and the lamination direction T of 0.12 mm or more and 0.9 mm or less.

The component main body 11 has a substantially rectangular parallelepiped shape. The component main body 11 includes a pair of main surfaces 17a opposed to each other in the lamination direction T, a pair of lateral surfaces 17b opposed to each other in the width direction W, and a pair of end surfaces 17c opposed to each other in the length direction L.

The component main body 11 includes the inner layer portion 12 therein. The inner layer portion 12 has a multilayer configuration in which a plurality of internal electrode layers 122 and a plurality of dielectric layers 121 are alternately laminated in the lamination direction T. Four surfaces on both sides in the width direction W and both sides in the lamination direction T of the inner layer portion 12 are covered with outer layer dielectric ceramic layers 13 made of the same material as the dielectric ceramic layers.

The internal electrode layers 122 are made of metal materials such as Ni, Cu, Ag, Pd, Ag—Pd alloy, Au, and the like, but are not limited to these metal materials and may be made of other electrically conductive materials.

The dielectric layers 121 and the outer layer dielectric ceramic layers 13 are formed by firing ceramic materials having barium titanate as a main component or other high permittivity ceramic materials (for example, those having CaTiO₃, SrTiO₃, CaZrO₃, and the like as main components).

The pair of external electrodes 16 are provided at both end portions in the length direction L of the component main body 11, respectively. Each of the external electrodes 16 covers a corresponding one of the pair of end surfaces 17c of the component main body 11. In addition, the pair of external electrodes 16 may also be provided on portions of the pair of main surfaces 17a and portions of the pair of lateral surfaces 17b, respectively. Among the plurality of internal electrode layers 122 in the inner layer portion 12, one of the internal electrode layers adjacent to each other in the lamination direction T is connected to one external electrode 16, and the other is connected to the other external electrode. Each of the pair of external electrodes 16 includes an end surface 16a in the length direction L.

Each of the external electrodes 16 includes, for example, a laminated film of a sintered metal layer and a plated layer. The sintered metal layer is formed by firing paste of Cu, Ni, Ag, Pd, Ag—Pd alloy, Au, and the like, for example. The plated layer includes, for example, a Ni plated layer and a Sn plated layer covering the Ni plated layer.

The multilayer ceramic capacitor 10 is manufactured, for example, by forming the pair of external electrodes 16 by firing or plating after the component main body 11 is fired. In some cases, a portion of the external electrode 16 is fired simultaneously with the component main body 11, and then the plated layer of the external electrode 16 is formed.

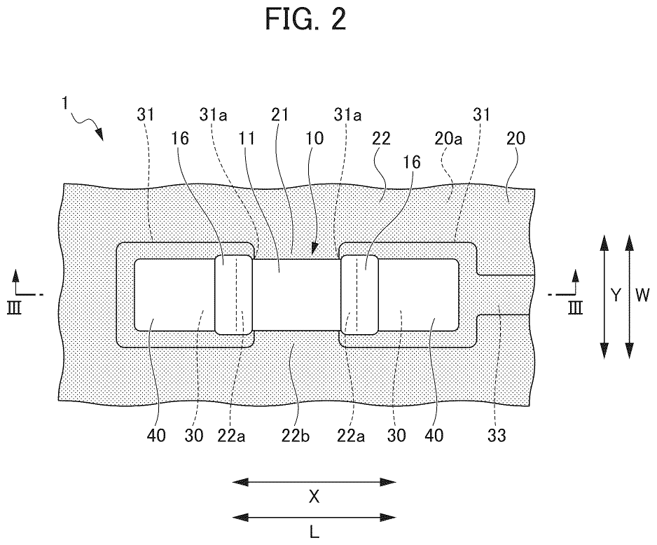

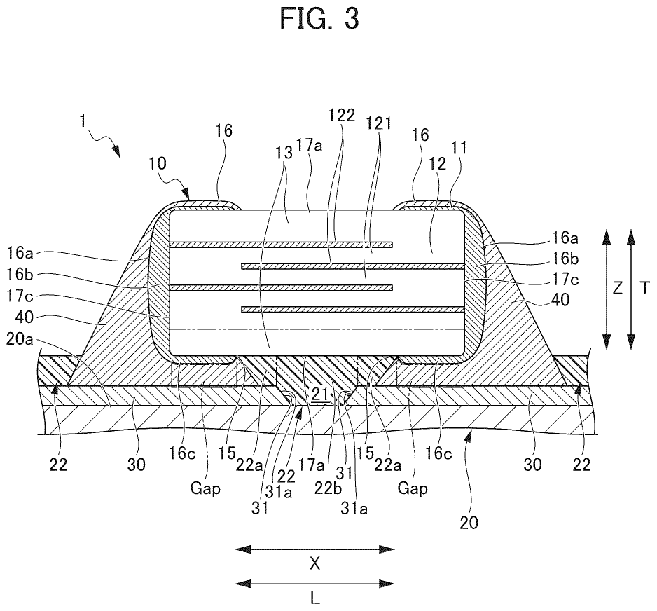

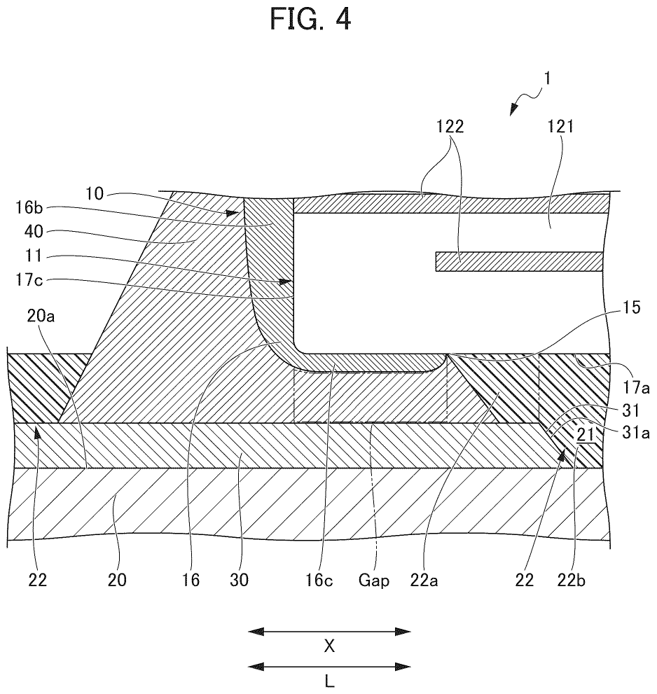

As shown in FIGS. 2 to 4, the mounting structure 1 includes a substrate 20, a pair of lands 30 provided on the substrate 20 and spaced apart from each other, solder 40 provided on each of the lands 30, and the multilayer ceramic capacitor 10. The multilayer ceramic capacitor 10 is mounted on the substrate 20 by soldering.

The substrate 20 is formed in a sheet shape from a material made of an insulating material such as resin, glass, glass epoxy, paper phenol, or ceramics.

Wiring 33 is formed on the surface 20a of the substrate 20. The wiring 33 is in a discontinuous state with a separation portion 21 interposed therebetween, and a pair of lands 30, which are portions of the wiring 33 and are portions connected to the external electrodes 16, are exposed on both sides of the separation portion 21. The pair of lands 30 are provided on the surface 20a of the substrate 20 and spaced apart from each other. Therefore, the separation portion 21 can also be referred to as a region between the pair of lands 30. Each of the pair of lands 30 is provided in parallel such that positions in a direction orthogonal to a direction in which the lands 30 are aligned are the same as each other.

The wiring 33 including the lands 30 is formed by depositing a highly electrically conductive metal such as Cu or Ag on the surface 20a of the substrate 20. Each of the pair of lands 30 has a rectangular shape in plan view and has substantially the same shape and dimensions as others thereof.

In the present specification, a direction orthogonal to the surface 20a of the substrate 20 is defined as a “Z direction”. A direction orthogonal to the Z direction and a direction in which the pair of lands 30 are provided adjacent to each other is defined as an “X direction”. A direction orthogonal to the X direction and the Z direction is defined as a “Y direction”. In the X direction, a direction in which the pair of lands 30 are spaced apart is defined as a “separation direction”, and a direction in which the pair of lands 30 are opposed to each other is defined as an “opposing direction”. In the present specification, “thickness of the land” indicates a dimension of the land 30 in the Z direction.

Peripheral edge portions of the pair of lands 30 in the X direction and the Y direction are defined as “peripheral edge portions 31”. Among the peripheral edge portions 31, an edge adjacent to the separation portion 21 is defined as an “inner edge 31a”. The inner edge 31a has a linear shape extending in the Y direction.

The surface 20a of the substrate 20 is covered with an insulating film 22. The insulating film 22 may be made of an insulating material, for example, a solder resist, an insulating coating material for substrates mainly composed of resin such as a polyolefin resin, acrylic resin, and polyurethane resin, and the like. The insulating film 22 extends to each of the lands 30, and a portion of each of the lands 30 adjacent to the peripheral edge portion 31 is covered with the insulating film 22. The peripheral edge portion 31 of each of the lands 30 is covered with the insulating film 22. In the separation portion 21, the surface 20a of the substrate 20 is covered with the insulating film 22. In FIG. 2, portions where the insulating film 22 is provided are shown with dot hatching.

In the insulating film 22, a portion provided on the surface of each of the lands 30 is defined as an “insulating film 22a”, and a portion provided in a region overlapping with the separation portion 21 when viewed in the Z direction is defined as an “insulating film 22b”. The insulating film 22 provided in the separation portion 21 is included in the insulating film 22b. In a case where each of the inner edges 31a of the lands 30 is a sloped surface that slopes in a direction approaching the substrate 20 as it goes toward the opposing direction, the insulating film 22 provided in a region overlapping with the sloped surface when viewed in the Z direction is included in the insulating film 22b and is not included in the insulating film 22a. In the present specification, “thickness of the insulating film 22” indicates a dimension of the insulating film 22 in the Z direction.

In the multilayer ceramic capacitor 10 mounted on the substrate 20, the length direction L is substantially along the X direction, the width direction W is substantially along the Y direction, and the lamination direction T is substantially along the Z direction. Accordingly, one main surface 17a of the component main body 11 is opposed to the surface 20a of the substrate 20 substantially in parallel. In addition, the multilayer ceramic capacitor 10 does not necessarily have to be mounted on the substrate 20 with the main surface 17a facing the substrate 20, and may be mounted on the substrate 20 with one lateral surface 17b facing the substrate 20.

In the multilayer ceramic capacitor 10, one external electrode 16 is connected to one land 30 via the solder 40, and the other external electrode 16 is connected to the other land 30 via the solder 40. The end surface 16a of each of the external electrodes 16 is substantially covered with the solder 40. In addition, the end surface 16a of each of the external electrodes 16 may be partially covered with the solder 40. The multilayer ceramic capacitor 10 is provided such that the middle in the width direction W substantially coincides with the middle of each of the lands 30 in the width direction W.

Each of the pair of external electrodes 16 includes a flat plate-shaped end surface covering portion 16b that covers the end surface 17c of the component main body 11, and an extension portion 16c that extends from the end surface covering portion 16b toward the opposing direction and is provided on portions of the pair of main surfaces 17a and the pair of lateral surfaces 17b. The extension portion 16c covers only a portion adjacent to the end surface 17c of each surface on each of the main surfaces 17a and each of the lateral surfaces 17b. The extension portion 16c has a rectangular tubular shape as a whole. The end portion of each of the extension portions 16c in the opposing direction corresponds to a boundary portion between the external electrode 16 and the component main body 11 (hereinafter referred to as “boundary portion 15”). The extension portion 16c does not necessarily have a rectangular tubular shape as a whole. The extension portion 16c does not need to extend to all surfaces among the respective main surfaces 17a and the respective lateral surfaces 17b, and it is sufficient that the extension portion extends to at least one surface among the respective main surfaces 17a and the respective lateral surfaces 17b that is opposed to the substrate 20.

The extension portion 16c that covers one main surface 17a of the component main body 11 opposed to the substrate 20 is connected to a corresponding one of the lands 30 via a solder 40. The end portion of the extension portion 16c in the opposing direction (the boundary portion 15) is located in the separation direction from the inner edge 31a of the land 30 connected to the extension portion 16c. In addition, the end portion of the extension portion 16c in the opposing direction (the boundary portion 15) may be provided in the opposing direction from the inner edge 31a of the land 30 connected to the extension portion 16c or at substantially the same position as the inner edge 31a. At this time, the insulating film 22a may be provided between the extension portion 16c and the land 30, or the insulating film 22a may not necessarily be provided.

The insulating film 22b fills the region between the substrate 20 and the component main body 11 without gaps. The dimension of the insulating film 22 in the Z direction is the same as the separation dimension between the substrate 20 and the component main body 11. The insulating film 22b supports the component main body 11 on the substrate 20. The insulating film 22b corresponds to a support member (specifically, a first support member). As used herein, “support member” refers to any structural element with a mechanical rigidity sufficient to maintain a gap during a solder reflow process. The insulating film 22b may be provided to partially fill the region between the substrate 20 and the component main body 11. That is, the region between the substrate 20 and the component main body 11 may partially include regions where the insulating film 22 does not exist. At this time, the insulating film 22a can also support the component main body 11 on the lands 30.

The insulating film 22a is continuous with the insulating film 22b and extends from the insulating film 22b in the separation direction. The dimension of the insulating film 22a in the Z direction is the same as the separation dimension between the component main body 11 and the land 30. The insulating film 22a and the insulating film 22b have flush surfaces (surfaces on the side separated from the substrate 20 in the Z direction). The insulating film 22a supports the component main body 11 on the lands 30. The insulating film 22a corresponds to a support member (specifically, a second support member).

Each end portion of the insulating film 22a in the separation direction is in contact with the boundary portion 15. The boundary portion 15 is covered by the insulating film 22b. Each end portion of the insulating film 22b in the separation direction has a sloped surface, specifically, a sloped surface that slopes toward the substrate 20 as it goes toward the opposing direction. The insulating film 22a does not extend in the separation direction from the boundary portion 15. Each end portion of the insulating film 22a in the separation direction does not need to be in contact with the boundary portion 15. For example, the insulating film 22a may not necessarily exist around the boundary portion 15 due to voids or the like. Further, the insulating film 22a may extend in the separation direction from the boundary portion 15.

The end portion of the solder 40 in the opposing direction is in contact with the insulating film 22a. The end portion of the solder 40 on the opposing side has a sloped surface, specifically, a sloped surface that slopes toward the side approaching the substrate 20 as it goes toward the opposing direction. Since the end portion of each of the insulating films 22a in the separation direction has a sloped surface that slopes toward the substrate 20 as it goes toward the opposing direction, it is possible to suppress the solder 40 from riding up on the insulating film 22a. In addition, the end portion of the solder 40 in the opposing direction does not need to be in contact with the insulating film 22a. That is, voids or the like may be interposed between the end portion of the solder 40 in the opposing direction and the insulating film 22.

The region sandwiched between the extension portion 16c and the land 30 is filled with solder 40 over the entire area. This makes it possible to firmly bond the external electrode 16 to the land 30.

The type of solder 40 is not particularly limited as long as it has characteristics suitable for each external electrode 16 and each land 30, and may be, for example, Sn—Pb solder, Sn—Ag—Cu solder, Sn—Cu solder, Sn—Bi solder, or the like.

A gap Gap is provided between the land 30 and the extension portion 16c of the external electrode 16 opposed to the land 30. The gap Gap can also be referred to as a region sandwiched between the extension portion 16c and the land 30. The entire gap Gap overlaps with the component main body 11 when viewed in the Z direction.

The dimension of the gap Gap in the Z direction corresponds to the thickness of the insulating film 22b between the component main body 11 and the substrate 20 and the thickness of the insulating film 22a between the component main body 11 and the land 30. That is, the dimension of the gap Gap in the Z direction can be adjusted by adjusting the thickness of the insulating film 22a and the thickness of the insulating film 22b.

The solder 40 is provided in the gap Gap, and more specifically, fills the gap Gap, i.e., at least a portion of the gap contains a solder volume having a thickness that entirely fills the Gap without any clearance. Therefore, the dimension of the gap Gap in the Z direction is identical to the dimension of the solder 40 provided in the gap Gap in the Z direction. In the present specification, “thickness of solder” stands for the dimension of the solder in the Z direction. In addition, the region sandwiched between the extension portion 16c and the land 30 does not need to be filled with the solder 40, and the solder 40 may be partially present or may not be present. At this time, in the region sandwiched between the extension portion 16c and the land 30, a void or the insulating film 22a may be present instead of the solder 40.

Stress may act on the ceramic sintered body near the tip portion of the external electrode 16 due to thermal shock or the like. In such a case, there is a possibility that cracks may occur in the component main body 11 starting from the boundary portion 15 between the edge of the extension portion 16c of the external electrode 16 and the component main body 11.

Therefore, the thickness of the solder 40 provided in the region sandwiched between the extension portion 16c and the land 30 (that is, the gap Gap) may be 1 μm or more and 100 μm or less. In such a case, stress is less likely to act on the boundary portion 15 and, resulting in suppressing the occurrence of cracks. It is possible to make not only stress caused by thermal shock, but also stress caused by deflection of the substrate 20 less likely to act on the boundary portion 15.

It is considered that, as the contact area between the extension portion 16c and the solder 40 becomes larger, stress caused by thermal shock or the like becomes more likely to act on the boundary portion 15. In the mounting structure 1, the contact area between the extension portion 16c and the solder 40 is relatively large. However, by setting the thickness of the solder 40 within the above-described range, it is possible to make stress less likely to act on the boundary portion 15 and, therefore, it is possible to suppress the occurrence of cracks.

The distance in the Z direction between the land 30 and the extension portion 16c (in other words, the dimension of the gap Gap in the Z direction) may be 1 μm or more and 100 μm or less. Since the thickness of the solder 40 is determined according to the dimension of the gap Gap in the Z direction, it is thereby possible to adjust the thickness of the solder 40 to a suitable range.

The thickness of the insulating film 22a may be adjusted such that the separation dimension between the extension portion 16 c and the land 30 falls within a range of 1 μm or more and 100 μm or less. In other words, the thickness of the insulating film 22a may be in a range such that the dimension obtained by subtracting the thicknesses of the land 30 and the extension portion 16c from the thickness of the insulating film 22 b is 1 μm or more and 100 μm or less. In such a case, it is possible to set the dimension of the gap Gap in the Z direction to a desired dimension and to set the thickness of the solder 40 provided in the gap Gap to a desired dimension.

The thicknesses of the insulating film 22, the land 30, and the solder 40 provided in the gap Gap are measured, for example, in a cross section obtained by cutting the mounting structure 1 parallel to the X direction and the Z direction so as to pass through the middle portion of the multilayer ceramic capacitor 10 in the Y direction. The value of the thickness of the solder 40 is, for example, an average value of values obtained by measuring the thickness of the solder 40 at a plurality of (for example, three) positions arranged at equal intervals in the X direction in the cross section. The same applies to the insulating film 22 and the land 30.

As described above, the boundary portion 15 is in contact with the insulating film 22a. Therefore, it is possible to suppress contact between the boundary portion 15 and the solder 40. This makes it possible to make stress less likely to act on the boundary portion 15 and, therefore, it is possible to suppress occurrence of cracks.

In the first embodiment, soldering with the solder 40 is performed, for example, by reflow. That is, the multilayer ceramic capacitor 10 can be reflow-mounted on the substrate 20. Hereinafter, a mounting method of the multilayer ceramic capacitor 10 will be described.

First, prior to soldering, the insulating film 22 is provided on the substrate 20. The insulating film 22 is provided, for example, so as to cover a portion of the land 30 including the peripheral edge portion 31. At this time, the thickness of the insulating film 22 is adjusted such that the dimension of the gap Gap in the Z direction becomes a desired dimension. Next, a paste-form solder material is applied to a region of the land 30 that is not covered by the insulating film 22. Next, the multilayer ceramic capacitor 10 is provided at a predetermined position on the land 30. The external electrode 16 sinks into the paste-form solder material until the component main body 11 comes into contact with the insulating film 22a and the insulating film 22b. The gap Gap is formed between the extension portion 16c of the external electrode 16 and the land 30. The gap Gap is in a state of being filled with the solder material. A portion of the solder material is pushed out from between the extension portion 16c and the land 30 and spreads on the end surface covering portion 16b of the external electrode 16. In this state, the solder material solidifies, and the external electrode 16 and the land 30 are connected by the solder 40.

According to the mounting structure 1 according to the first embodiment, it is possible to achieve the following advantageous effects.

According to the above embodiment, the thickness of the solder 40 provided in the region interposed between the extension portion 16c and the land 30 may be 1 μm or more and 100 μm or less.

Stress may act on the ceramic sintered body near the tip portion of the external electrode 16 due to thermal shock or the like. In such a case, cracks may occur in the component main body 11, starting from the vicinity of the boundary portion 15 between the edge of the extension portion 16c of the external electrode 16 and the component main body 11. However, by setting the thickness of the solder 40 provided in the gap Gap in a range of 1 μm or more and 100 μm or less, it is possible to make stress less likely to act on the boundary portion 15. This makes it possible to suppress crack occurrence.

According to the above embodiment, the distance in the Z direction between the land 30 and the extension portion 16c may be 1 μm or more and 100 μm or less.

This makes it possible to adjust the thickness of the solder 40 to a suitable range.

According to the above embodiment, the insulating film 22a is provided in the region interposed between the component main body 11 and the land 30. The insulating film 22a supports the component main body 11 on the lands 30. Further, the insulating film 22b is provided in the region between the pair of lands 30 as viewed in the Z direction. The insulating film 22b supports the component main body 11 on the substrate 20.

With such a configuration, by adjusting the dimension in the Z direction of the insulating film 22a and the insulating film 22b, it is possible to adjust the dimension in the Z direction of the gap Gap and the thickness of the solder 40 provided in the gap Gap to the desired dimensions.

According to the above embodiment, the thickness of the insulating film 22a may be adjusted such that the separation dimension between the extension portion 16c and the land 30 falls within a range of 1 μm or more and 100 μm or less. Further, the thickness of the insulating film 22b may be set such that the dimension obtained by subtracting the thickness of the land 30 from the thickness of the insulating film 22b corresponds to the thickness of the insulating film 22a, and similarly to the above, the separation dimension between the extension portion 16c and the land 30 falls within a range of 1 μm or more and 100 μm or less.

In such cases, it is possible to set the dimension in the Z direction of the gap Gap in a range of 1 μm or more and 100 μm or less, and to set the thickness of the solder 40 provided in the gap Gap in a range of 1 μm or more and 100 μm or less. This makes it possible to suppress crack occurrence in the electronic component.

### Second Embodiment

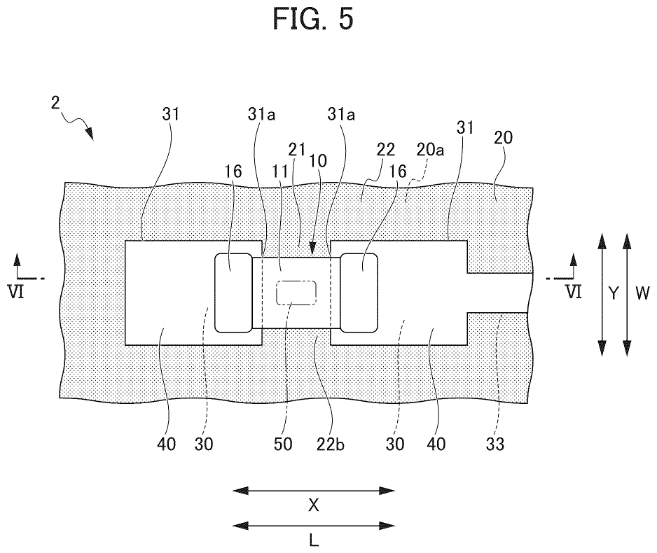

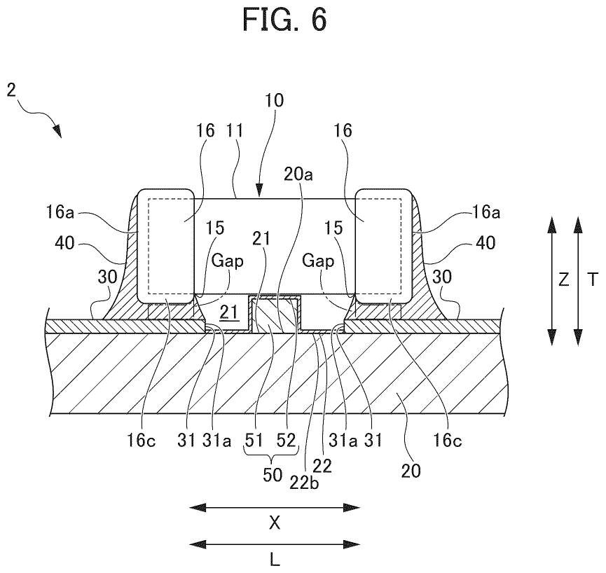

Next, a second embodiment will be described with reference to FIGS. 5 and 6. The second embodiment is achieved by modifying a portion of the first embodiment described above. Therefore, in the reference drawings, the same reference numerals are assigned to the same components as those in the first embodiment, and descriptions thereof are omitted, and only the differences will be mainly described. In FIG. 5, the portion where the insulating film 22 is provided is indicated by dot hatching. In FIG. 6, the illustration of the internal configuration of the multilayer ceramic capacitor 10 is omitted.

In the mounting structure 2 of the second embodiment, a support member 50 is provided between the pair of lands 30. The support member 50 is a member that supports the component main body 11 on the substrate 20, and corresponds to a first support member. The support member 50 is provided substantially in the middle of the separation portion 21. The support member 50 includes a block member 51 having a rectangular parallelepiped shape as a whole. The block member 51 is made of, for example, a metal, and specifically is a copper foil. The block member 51 is made of a material having a higher melting point than solder. The block member 51 is provided on the surface 20a of the substrate 20. The block member 51 is bonded to the surface 20a by, for example, an adhesive.

The material of the block member 51 is not limited to metal. The block member 51 does not need to be made of a single material. For example, the block member 51 may be formed by laminating a plurality of layers, each made of mutually different materials.

The surface of the separation portion 21 is covered with an insulating film 22b made of solder resist. However, in the second embodiment, the insulating film 22b has a thin film shape and has a smaller thickness than that in the first embodiment. Therefore, in the region between the substrate 20 and the component main body 11, there is a space where solder resist is not provided. In this manner, the insulating film 22b does not necessarily need to fill the region between the substrate 20 and the component main body 11 without gaps.

The insulating film 22b covers the surface of the block member 51. Therefore, the support member 50 includes the block member 51 and a resist film portion 52 that covers the surface of the block member 51. Silk may be further applied to the surface of the resist film portion 52. The block member 51 does not necessarily need to be covered with the insulating film 22, and the resist film portion 52 is not an essential configuration in the support member 50.

The support member 50 is tightly sandwiched between the component main body 11 and the substrate 20. The dimension of the support member 50 in the Z direction is greater than the thickness of the land 30. In the second embodiment, the insulating film 22 is not provided between the land 30 and the extension portion 16c. Therefore, the separation distance between the component main body 11 and the substrate 20 is the same as the dimension of the support member 50 in the Z direction. A gap Gap is provided between the component main body 11 and the land 30. The dimension of the gap Gap in the Z direction is the same as the dimension obtained by subtracting the thickness of the land 30 from the dimension of the support member 50 in the Z direction. Therefore, by adjusting the dimension of the support member 50 in the Z direction, it is possible to adjust the dimension of the gap Gap in the Z direction. It is possible to adjust the thickness of the solder 40 provided in the gap Gap.

The dimension of the support member 50 provided in the separation portion 21 in the Z direction may be set such that the separation dimension between the extension portion 16c and the land 30 falls within a range of 1 μm or more and 100 μm or less. In that case, it is possible to set the thickness of the solder 40 provided in the gap Gap to 1 μm or more and 100 μm or less. It is possible to suppress the occurrence of cracks in the multilayer ceramic capacitor 10.

In the second embodiment, the solder 40 extends to the inner edge 31a of the land 30 and covers the end portion of the extension portion 16c in the opposing direction. Even in such a configuration, by setting the thickness of the solder 40 within the above range, it is possible to sufficiently suppress the occurrence of cracks.

The position where the support member 50 can be provided is not limited to on the separation portion 21. For example, the support member 50 may be provided in the gap Gap, and the block member 51 may be provided on a corresponding one of the lands 30. In that case, the dimension of the support member 50 may be provided in the gap Gap in the Z direction is 1 μm or more and 100 μm or less. This makes it possible to set the thickness of the solder 40 provided in the gap Gap within a desired range.

The present disclosure is not limited to the above embodiments, and modifications and improvements within a range that can achieve the above advantages.

For example, in the first embodiment described above, the end portion of each of the insulating films 22a in the separation direction extends to a position in contact with the end portion of a corresponding one of the extension portions 16c in the opposing direction. However, the insulating film 22a may extend further in the separation direction from the boundary portion 15. The insulating film 22a may be provided in a region sandwiched between the extension portion 16c and the land 30, and the region sandwiched between the extension portion 16c and the land 30 does not need to be filled with solder 40 over the entire area. In that case, it is possible to increase the distance between the solder 40 and the boundary portion 15, and thus it is possible to more suitably suppress the solder 40 from contacting the boundary portion 15. However, from the viewpoint that the external electrode 16 can be firmly soldered by the land 30, may adopt the configuration of the first embodiment described above.

The support member 50 is not limited to the configuration of the second embodiment as long as it is possible to maintain the distance between the extension portion 16c of the external electrode 16 and the substrate 20. The support member may be, for example, an adhesive. In that case, the adhesive may be, for example, an epoxy resin adhesive. However, the support member 50 may be made of a material having a melting point higher than that of solder. In addition, solder connecting the external electrode and the land does not correspond to the support member.

The multilayer ceramic capacitor 10 in the above embodiments is an example of an electronic component, and the electronic component is not limited thereto, and other two-terminal electronic components such as inductors are also applicable. For example, in the case of an inductor, the component main body is made of magnetic ceramics or the like.

In addition, the present disclosure includes the following combinations.
<1> A mounting structure for an electronic component includes: a pair of lands provided on a substrate and spaced apart from each other; solder provided on each of the pair of lands; and an electronic component including a component main body including dielectric layers and internal electrode layers that are laminated, a pair of main surfaces opposed to each other in a lamination direction, a pair of lateral surfaces opposed to each other in a width direction orthogonal to the lamination direction, and a pair of end surfaces opposed to each other in a length direction orthogonal to the lamination direction and the width direction, and a pair of external electrodes each provided on a corresponding one of the pair of end surfaces, each of the pair of external electrodes being connected to a corresponding one of the pair of lands via the solder. Each of the pair of external electrodes includes an extension portion extending to at least a portion of each of the main surfaces and each of the lateral surfaces. When a direction substantially orthogonal to a surface of the substrate is defined as a Z direction, a dimension in the Z direction of the solder provided in a region between a corresponding one of the pair of lands and the extension portion is 1 μm or more and 100 μm or less.
<2> In the mounting structure for an electronic component as described in <1> above, at least one of the substrate or one of the pair of lands includes a support member that supports the component main body.
<3> In the mounting structure for an electronic component as described in <2> above, the support member includes an insulating material.
<4> In the mounting structure for an electronic component as described in <2> or <3> above, the support member includes a first support member provided in a region between the pair of lands, and a dimension of the first support member in the Z direction is in a range such that a dimension obtained by subtracting a dimension of one of the pair of lands in the Z direction and a dimension of the extension portion in the Z direction from the dimension of the first support member in the Z direction is 1 μm or more and 100 μm or less.
<5> In the mounting structure for an electronic component as described in any one of <2> to <4> above, the support member includes a second support member provided in a region between a corresponding one of the pair of lands and the extension portion, and a dimension of the second support member in the Z direction is 1 μm or more and 100 μm or less.
<6> A mounting structure for an electronic component includes a pair of lands provided on a substrate and spaced apart from each other; solder provided on each of the pair of lands; and an electronic component including a component main body including dielectric layers and internal electrode layers that are laminated, a pair of main surfaces opposed to each other in a lamination direction, a pair of lateral surfaces opposed to each other in a width direction orthogonal to the lamination direction, and a pair of end surfaces opposed to each other in a length direction orthogonal to the lamination direction and the width direction, and a pair of external electrodes each provided on a corresponding one of the pair of end surfaces, each of pair of the external electrodes being connected to a corresponding one of the pair of lands via the solder. Each of the pair of external electrodes includes an extension portion extending to at least a portion of each of the main surfaces and each of the lateral surfaces. When a direction substantially orthogonal to a surface of the substrate is defined as a Z direction, a distance in the Z direction between a corresponding one of the pair of lands and the extension portion is 1 μm or more and 100 μm or less.

### EXPLANATION OF REFERENCE NUMERALS

1 mounting structure
10 multilayer ceramic capacitor (electronic component)
11 component main body
16 external electrode
16b end surface covering portion
16c extension portion
17a main surface
17b lateral surface
17c end surface
20 substrate
22a insulating film (second support member and insulating material)
22b insulating film (first support member and insulating material)
30 land
40 solder
50 support member (first support member)
51 block member (first support member)
52 resist film portion (first support member and insulating material)
121 dielectric layer
122 internal electrode layer

What is claimed is:

1. A mounting structure for an electronic component comprising:
a pair of lands provided on a substrate and spaced apart from each other;
solder provided on each of the pair of lands; and
an electronic component including
a component main body including dielectric layers and internal electrode layers that are laminated, a pair of main surfaces opposed to each other in a lamination direction, a pair of lateral surfaces opposed to each other in a width direction orthogonal to the lamination direction, and a pair of end surfaces opposed to each other in a length direction orthogonal to the lamination direction and the width direction, and
a pair of external electrodes each provided on a corresponding one of the pair of end surfaces, each of the pair of external electrodes being connected to a corresponding one of the pair of lands via the solder,
wherein each of the pair of external electrodes includes an extension portion extending to at least one of a portion of each of the main surfaces and each of the lateral surfaces, and
wherein, when a direction substantially orthogonal to a surface of the substrate is defined as a Z direction, a dimension in the Z direction of a gap defined between a corresponding one of the pair of lands and the extension portion is between 1 μm and 100 μm, inclusive.

2. The mounting structure for an electronic component according to claim 1, wherein at least one of the substrate or one of the pair of lands includes a support member that supports the component main body.

3. The mounting structure for an electronic component according to claim 2, wherein the support member includes an insulating material.

4. The mounting structure for an electronic component according to claim 2, wherein
the support member includes a first support member provided in a region between the pair of lands, and
a dimension of the first support member in the Z direction is in a range such that a dimension obtained by subtracting a dimension of one of the pair of lands in the Z direction and a dimension of the extension portion in the Z direction from the dimension of the first support member in the Z direction is between 1 μm and 100 μm, inclusive.

5. The mounting structure for an electronic component according to claim 2, wherein
the support member includes a second support member provided in a region between a corresponding one of the pair of lands and the extension portion, and
a dimension of the second support member in the Z direction is between 1 μm and 100 μm, inclusive.

6. The mounting structure according to claim 5, wherein an end portion of the second support member has a sloped surface configured to suppress the solder from riding up on the second support member.

7. The mounting structure according to claim 2, wherein an end portion of the solder is in contact with the support member.

8. The mounting structure according to claim 1, wherein the dimension in the Z direction of the gap corresponds to a thickness of the solder provided in the gap.

9. The mounting structure according to claim 1, wherein an end portion of the extension portion in an opposing direction defines a boundary portion between the external electrode and the component body, and the boundary portion is covered by the support member.

10. A mounting structure for an electronic component comprising:
a substrate having a pair of lands spaced apart by a separation portion;
an electronic component having a component body and an external electrode, the external electrode having an extension portion overlapping one of the pair of lands; and
a support member disposed on at least one of the substrate or the one of the pair of lands, the support member being configured to maintain a gap between the extension portion and the one of the pair of lands in a Z direction orthogonal to a surface of the substrate,
wherein a thickness of a solder disposed in the gap is between 1 μm and 100 μm.

11. The mounting structure according to claim 10, wherein the support member includes a first support member provided in the separation portion.

12. The mounting structure according to claim 11, wherein the first support member includes a block member having a melting point higher than a melting point of the solder.

13. The mounting structure according to claim 11, wherein the support member includes a second support member provided on the one of the pair of lands.

14. The mounting structure according to claim 13, wherein an end portion of the second support member has a sloped surface configured to suppress the solder from riding up on the second support member.

15. The mounting structure according to claim 10, wherein an end portion of the extension portion in an opposing direction defines a boundary portion between the external electrode and the component body, and the boundary portion is covered by the support member.

16. A method of manufacturing a mounting structure for an electronic component, the method comprising:
providing an insulating film on a substrate having a pair of lands to define a support member;
applying a solder material to a portion of the pair of lands not covered by the insulating film;
placing an electronic component on the solder material such that a component body of the electronic component contacts the support member; and
reflowing the solder material to form a solder connection having a thickness of 1 μm to 100 μm in a region between an extension portion of an external electrode of the electronic component and one of the pair of lands.
